(19) United States
(12) Patent Application Publication
(10) Pub. No.: US 2015/0263189 A1
(43) Pub. Date: Sep. 17, 2015

(54) THIN FILM AND METHOD FOR MANUFACTURING THE SAME

(71) Applicant: Electronics and Telecommunications Research Institute, Daejeon (KR)

(72) Inventors: Sun Jin YUN, Daejeon (KR); JungWook Lim, Daejeon (KR)

(73) Assignee: Electronics and Telecommunications Research Institute, Daejeon (KR)

(21) Appl. No.: 14/727,936

(22) Filed: Jun. 2, 2015

Related U.S. Application Data
(62) Division of application No. 13/224,322, filed on Sep. 1, 2011.

(30) Foreign Application Priority Data
Sep. 2, 2010 (KR) 10-2010-0086135
Dec. 23, 2010 (KR) 10-2010-0133200

(51) Int. Cl. H01L 31/0216

(52) U.S. Cl. CPC H01L 31/02168

(57) ABSTRACT

Provided embodiments are a thin film including a support material and nano particles having different density from that of the support material, and a method for manufacturing the same. Due to the density difference, the nano particles are intensively concentrated on an upper or lower part of the support material. The inventive concept also discloses a thin film capable of increasing surface roughness and a method for manufacturing the same. The thin film includes a support material, and particles contained therein. The particles may have lower density than that of the support material, and increase surface roughness at an upper part of the support material.

### CROSS-REFERENCE TO RELATED APPLICATIONS

This is a Divisional of U.S. application Ser. No. 13/224,322, filed on Sep. 1, 2011. This U.S. non-provisional patent application claims priority under 35 U.S.C. §119 of Korean Patent Application Nos. 10-2010-0086135, filed on Sep. 2, 2010 and 10-2010-0133200, filed on Dec. 23, 2010. The disclosure of these prior U.S. and Korean Applications are incorporated herein by reference.

### BACKGROUND OF THE INVENTION

The present invention disclosed herein relates to a thin film and a method for manufacturing the same, and more particularly, to a thin film having a well controlled surface roughness and high surface roughness and a method for manufacturing the same.

Generally, a solar cell is a kind of photovoltaic energy conversion system which converts sunlight energy to electric energy. A solar cell generates electric power by using limitless solar energy, and the generation of electric power does not result in pollution. Thus, a solar cell is in the spotlight as a future environmentally-friendly and clean energy source, and researches are being actively conducted for commercializing a solar cell. A solar cell may include a thin film such as an anti-reflective film for preventing sunlight from being reflected. However, a typical anti-reflective film does not have sufficient surface roughness.

### SUMMARY OF THE INVENTION

The present invention provides a thin film having increased surface roughness and a method for manufacturing the same.

The present invention also provides a thin film in which a density of an upper part thereof is different from that of a lower part thereof, and a method for manufacturing the same.

Embodiments of the inventive concept provide thin films including a support material, and particles contained therein, wherein a density of the particles is different from that of the support material, and the particles are intensively concentrated on an upper or lower part of the support material.

In some embodiments, the particles may have a lower density than that of the support material, and increase surface roughness at the upper part of the support material.

In other embodiments, the surface roughness may increase in proportion to the density difference between the particles and the support material.

In still other embodiments, the particles may have a lower refractive index than that of the support material.

In even other embodiments, the particles may have diameters of about 1 nm to about 500 nms. The surface roughness may be proportion to the diameters of the particles. Thus, the surface roughness may be larger than about 1 nm and smaller than about 500 nms.

In yet other embodiments, the support material may include at least one of aluminum oxide, titanium oxide, tantalum oxide, and zinc oxide.

In further embodiments, the particles may include at least one of silicon oxide and nitride oxide.

In other embodiments of the inventive concept, methods for manufacturing a thin film include preparing a substrate; coating particles and a precursor solution of a support material having a different density from that of the particles on the substrate; and generating the support material from the precursor solution after the particles are re-arranged on an upper or lower part of the precursor solution due to the density difference.

In some embodiments, the particles having a lower density than that of the support material may increase surface roughness at an upper part of the support material.

In other embodiments, the precursor solution may include a precursor of the support material and a solvent. The surface roughness may increase in proportion to concentration of the precursor in the precursor solution.

In still other embodiments, the surface roughness may increase in proportion to the density difference between the particles and the support material.

In even other embodiments, the surface roughness may increase in proportion to diameters of the particles.

In yet other embodiments, the precursor solution and the particles may be mixed with each other and then coated on the substrate. The particles may be dispersed in a dispersion solution and then mixed with the precursor solution. The precursor solution may be coated on the substrate by using at least one of a sol-gel method, a screen printing method, a spray method, a dipping method, and an inkjet printing method.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIGS. 1 to 3 are cross-sectional views illustrating a method for manufacturing a thin film according to an embodiment of the inventive concept;

FIG. 4 is an image of a thin film including a support material and nano-particles, which is taken by a transmission electron microscope; and

FIGS. 5A and 5B are images of thin films composed of nano-particles.

### DETAILED DESCRIPTION OF PREFERRED EMBODIMENTS

Preferred embodiments of the inventive concept will be described below in more detail with reference to the accompanying drawings. The inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like reference numerals refer to like elements throughout.

The terms used in the present description are not for limiting the inventive concept but for explaining the embodiments. The terms of a singular form may include plural forms unless otherwise specified. The meaning of “include,” “comprise,” “including,” or “comprising,” specifies a property, a region, a fixed number, a step, a process, an element and/or a component but does not exclude other properties, regions, fixed numbers, steps, processes, elements and/or components. The reference numerals presented according to a sequence of description are not limited to the sequence.

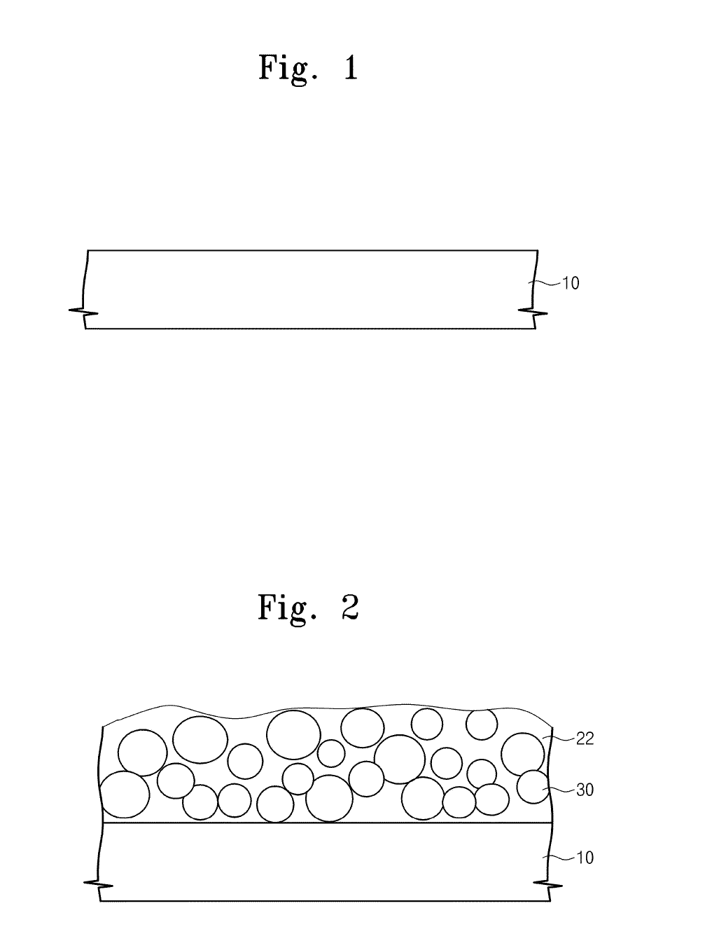

FIGS. 1 to 3 are cross-sectionals views illustrating a method for manufacturing a thin film according to an embodiment of the inventive concept.

Referring to FIGS. 1 to 3, for manufacturing a thin film 40 by using the method according to the embodiment of the inventive concept, a precursor solution 22 of a support material 20, with which nano-particles 30 are mixed, is coated on a prepared substrate 10. The precursor solution 22 mixed with the nano-particles 30 may be coated on the substrate 10 by using a sol-gel method, screen printing method, spray method, or dipping method. Next, the nano-particles 30 are concentrated or self-arranged on an upper part of the precursor solution 22 due to a density difference between the support material 20 and the nano-particles 30, and then, the support material 20 may be solidified. The nano-particles 30 on an upper part of the support 20 may increase surface roughness of the thin film 40.

The nano-particles 30 and the support material 20 may include an oxide and a nitride having different densities. Further, the nano-particles 30 may include metal. Because an oxide and a nitride are stable materials, the nano-particles 30 may be easily prepared, and the materials may be used as a protective layer, an anti-reflective layer, an insulating layer, or the like. The nano-particles 30 may include an oxide or nitride having lower density and lower refractive index than those of the support material 20. Due to the nano-particles 30, an upper part and a lower part of the thin film 40 may have different refractive indices. Since the nano-particles 30 are biasedly distributed on an upper part or lower part of the thin film 40, the refractive index difference between the upper part and the lower part may be induced. Therefore, the thin film 40 may be a multi-layered thin film in which layers have different refractive indices.

For instance, the nano-particles 30 may include a silicon oxide or silicon nitride. The nano-particles 30 and the support material 20 may be composed of different kinds of oxides. The support material 20 may include a metal oxide or metal nitride having higher density than that of the nano-particles 30. Also, the nano-particles 30 may include a metal oxide having lower density than that of the support material 20. Materials such as a silicon oxide, a silicon nitride, and a metal oxide may have characteristic density and refractive index as shown in Table 1.

TABLE 1

| Material | Density | Refractive index |
|---|---|---|
| SiO₂ | 2.2~2.3 | 1.45~1.5 |
| Si₃N₄ | 3.44 | 1.7~1.8 |
| Al₂O₃ | 3.5~3.9 | 1.65~1.70 |
| TiO₂ | 4.26 | 2.6~2.9 |
| ZnO | 5.0~5.6 | 2.0 |
| Ta₂O₅ | 8.2 | — |

In Table 1, oxides and nitride which have high densities have high refractive indices. Therefore, since different kinds of oxides and nitride have different densities, when a solvent is vaporized and a heat treatment is performed after the oxides and nitride are mixed with each other in the forms of the nano-particles 30 and the precursor solution 22, the oxides and nitride may be easily separated from each other.

Generally, in the case that a thin film is manufactured by using a mixture of different kinds of precursor solutions, the thin film may have a uniform composition because the precursors are uniformly mixed with each other and cross-linked with each other due to a following heat treatment process. However, in the case that the thin film 40 is manufactured by using the precursor solution 22 of the support material 20 with which the nano-particles 30 are mixed, a mixed solution in which the nano-particles 30 are uniformly dispersed is prepared and coated on the substrate 10, and a first heat treatment is performed at a low temperature of about 80° C. to about 150° C. Then, a solvent which makes the nano-particles 30 uniformly disperse in the precursor solution 22 vaporizes. The nano-particles 30 are re-distributed in the film due to a density difference between the nano-particles 30 and the precursor of support material before or after vaporizing the solvent or during the heat treatment at low temperature. The nano-particles 30 may be concentrated on an upper part or lower part of the precursor solution 22 due to the density difference. This is because the nano-particles 30 are prepared as a solid having a composition different from that of the support material 20 before the nano-particles 30 are added to the precursor solution 22 of the support material 20. Precursors in the precursor solution 22 are cross-linked with each other to be polymerized through a solidification process such as a heat treatment process, thereby generating the support material 20. Herein, reaction residues may vaporize to be eliminated. Therefore, the nano-particles 30 and the support material 20 having different densities are separated from each other or re-arranged due to the density difference so that light things are moved up and heavy things are moved down before solidification of supporting material 20, unless the nano-particles 30 and the support material 20 are chemically combined with each other in the precursor solution 22. Also, the separation or re-arrangement of multiple mixed materials may more actively occur before or during a following solidification process such as a heat treatment process. More specifically, the separation or re-arrangement of multiple mixed materials may more actively occur before or during a solidification process such as a second heat treatment process which seriously causes the cross-linking phenomenon. Typically, the second heat treatment process is performed at a temperature of about 200° C. to about 500° C. As described above, an upper part and a lower part of the thin film 40 may have different average densities and different average compositions.

Therefore, a density of an upper part of the thin film 40 is low and a density of a lower part thereof is high, and thus, optical usefulness of the thin film 40 is high. The thin film 40 may have a refractive index which gradually decreases from a lower part to an upper part. The nano-particles 30 may have a refractive index higher than that of air and lower than that of the support material 20. The thin film 40 may be an anti-reflective film which reduces reflection of light having an optically wider wavelength range than that of a thin film having a uniform refractive layer when light is incident to an upper part of the thin film 40 from the outside. These characteristics may be obtained by manufacturing a multi-layered thin film in the case of using a typical manufacturing method. However, according to the inventive concept, the same characteristics may be obtained by forming a single-layer film. Also, when light is incident to a lower part of the thin film 40, the thin film 40 may be a high reflective film having reflectivity that is gradually increases from a lower part thereof to an upper part thereof. The substrate 10 may include transparent material having a higher refractive index than that of the support material 20.

Particularly, surface roughness of the thin film 40 may increase in proportion to sizes of the nano-particles 30. Also, the surface roughness may be adjusted by a density difference between the nano-particles 30 and the support material 20. For instance, the change of surface roughness due to the density difference between the nano-particles 30 and the support material 20 is described as follows. It is assumed that the support material 20 is a fluid, and the nano-particles 30 are solid floating on the fluid. When a density of the nano-particles 30 is about a half of that of the support material 20, the surface roughness may be about a half of an average diameter of the nano-particles 30. When a density of the nano-particles 30 is about one third of that of the support material 20, the nano-particles 30 may protrude from the support material 20 as much as about two thirds of a volume of the nano-particles 30 maximally. Substantially, since the support material 20 is coated on a surface of the nano-particles 30, the thin film 40 may have higher surface roughness than calculated roughness.

Hereinafter, a method for manufacturing the thin film 40 including the support material 20 of aluminum oxide and the nano-particles 30 of silicon oxide will be described with reference to an exemplary experiment.

The nano-particles 30 of silicon oxide are mixed with the precursor solution 22 of aluminum oxide, and then, the precursor solution 22 is coated on the substrate 10. Herein, the nano-particles 30 may be dispersed in a dispersion solution before being mixed with the precursor solution 22. The precursor solution 22 may be coated on the substrate 10 by using a sol-gel method. The precursor solution 22 of aluminum oxide may include precursors of aluminum isopropoxide dissolved in a solvent. The precursors may be cross-linked with each other to be polymerized through a heat treatment at a temperature of about 200° C. to about 500° C. Prior to the heat treatment, the solvent may vaporize or may be eliminated from the support material 20 of aluminum oxide during a pre-heating process at a temperature 80˜120° C. During this pre-heating process and the heat treatment process, the nano-particles 30 of silicon oxide having lower density than that of aluminum oxide may be concentrated on an upper part of the support material 20. Table 2 shows a change of surface roughness according to manufacturing methods of the thin film 40.

TABLE 2

| | Surface |
|---|---|
| Manufacturing method | roughness (nm) |
| Thin film composed of only SiO₂ nano-particles | 1.54 |
| (average diameter of about 10 nm) | |
| (using 5% SiO₂ dispersion solution) | |
| Thin film composed of only Al₂O₃ support material | 0.30 |
| (AlO-precursor 2% solution) | |
| Thin film in which SiO₂ nano-particles (average | 4.6~5.0 |
| diameter of about 10 nm) are supported by Al₂O₃ | |
| support material | |
| (2% SiO₂ + 1% AlO-precursor) | |
| Thin film in which SiO₂ nano-particles (average | 5.44~6.00 |
| diameter of about 10 nm to about 15 nm) are | |
| supported by Al₂O₃ support material | |
| (2% SiO₂ + 2% AlO-precursor) | |

Herein, the thin film 40 has a thickness of about 40 nm to about 90 nm. Surface roughness of the thin film 40 was measured by using an atomic force microscope.

The aluminum oxide (Al₂O₃) thin film, which was manufactured by using only the precursor solution 22 of aluminum oxide (Al₂O₃), has very low surface roughness of about 0.30 nm. The silicon oxide (SiO₂) thin film, which was manufactured by using only the nano-particles 30 of silicon oxide (SiO₂) having an average diameter of about 10 nm, has low surface roughness of about 1.54 nm. A thin film of the nano-particles 30 may be manufactured by mixing the nano-particles 30 with a solvent such as isopropyl alcohol and then by coating the mixture on the substrate 10. The thin film 40 in which the silicon oxide nano-particles 30 are mixed with the support material 20 of aluminum oxide (Al₂O₃) may have high surface roughness of about 5 nm to about 6 nm. This result of experiment may be contrary to a skilled person's typical prediction that liquid precursors will fill gaps between the nano-particles 30 and will be solidified, and then surface roughness will be consequently reduced. Therefore, the thin film 40 including the support material 20 and the nano-particles 30 may have higher surface roughness than that of the thin film of the support material 20 or the thin film of the nano-particles 30.

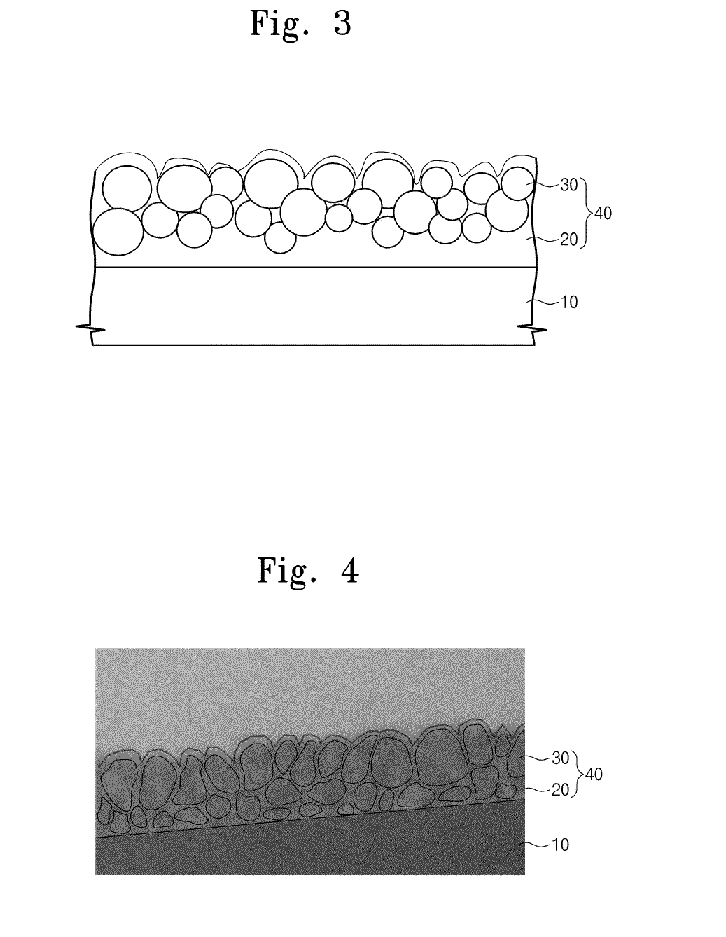

FIG. 4 is an image of the thin film 40 including the support material 20 and the nano-particles 30, which was taken by a transmission electron microscope. Referring to FIGS. 3 and 4, the thin film 40 may have surface roughness larger than several nm. The support material 20 composed of amorphous aluminum oxide and the nano-particles 30 of amorphous silicon oxide may not be measured by a transmission electron microscope. However, surface roughness of the thin film 40 may be measured by a transmission electron microscope and an atomic force microscope. The surface roughness of the thin film 40 may be measured as similar values by a transmission electron microscope and an atomic force microscope.

Referring to Table 2 again, the thin film 40 may have surface roughness which increases in proportion to concentration of precursors of the support material in the precursor solution 22. The thin film 40 may have higher surface roughness when concentration of aluminum oxide precursors of the precursor solution 22 is about 2% than when the concentration of aluminum oxide precursors of the precursor solution 22 is about 1%. As the precursor concentration increases in the precursor solution 22, an eduction amount of the support material 20 may increase. Therefore, the surface roughness of the thin film 40 may increase in proportion to a deposition amount of the support material 20 from the precursor solution 22, and the precursor concentration. As the precursor concentration increases in the precursor solution 22, a thickness of a film composed of support material formed by performing a coating operation once may increase.

The surface roughness may increase when a density difference between the nano-particles and the support material 20 becomes larger. For the same reason, when the nano-particles 30 of silicon oxide (SiO₂) are included in the support material 20 of titanium oxide (TiO₂) disclosed in Table 1, the thin film 40 may have high surface roughness. When the nano-particles 30 of silicon oxide (SiO₂) are included in the support material 20 of zinc oxide (ZnO) or tantalum oxide (Ta₂O₅), the thin film 40 may have higher surface roughness than when the support material 20 of titanium oxide (TiO₂) is used. Also, when the nano-particles 30 of silicon nitride (Si₃N₄) are included in the support material 20 of titanium oxide (TiO₂), zinc oxide (ZnO), or tantalum oxide (Ta₂O₅), the thin film 40 may obtain high surface roughness. Density and refractive index of the support material 20 may be adjusted according to precursor solutions 22 including a plurality of oxide precursors. Therefore, by using the method for manufacturing the thin film 40 according to the embodiment of the inventive concept, the surface roughness may be adjusted.

The surface roughness may increase in proportion to sizes of the nano-particles 30 included in the support material 20. The nano-particles 30 may have diameters of about 1 nm to about 500 nm. For instance, when the same support material 20 is used, the surface roughness of the thin film 40 may increase about five times when the nano-particles 30 have diameters of about 500 nm than when the nano-particles 30 have diameters of about 100 nm. Herein, the surface roughness may increase in proportion to a density difference between the support material 20 and the nano-particles 30. The nano-particles 30 having diameters of about 100 nm may be formed as the thin film 40 having surface roughness of about several nms to about 50 nm in the support material 20 of which density is less than double density of the nano-particles 30. Also, the nano-particles 30 having diameters of about 500 nm may be formed as the thin film 40 having surface roughness of about several nms to about 250 nm in the support material 20 of which density is less than double density of the nano-particles 30. When the density difference between the support material 20 and the nano-particles 30 is very large, the thin film 40 which includes the nano-particles 30 having diameters of about 500 nm may have surface roughness of about 500 nm maximally. Therefore, the thin film 40 may have the surface roughness corresponding to diameters of the nano-particles 30. For instance, as shown in Table 1, when the nano-particles 30 of silicon oxide having diameters of about 10 nm to about 15 nm are mixed with the support material 20 of aluminum oxide to form the thin film 40, the surface roughness is about 4.6 nm to about 6.0 nm. In the same manner, when the thin film 40 is formed by using the nano-particles of 30 having diameters of about 100 nm to about 150 nm, the surface roughness is about 46 nm to 60 nm. That is, the surface roughness of the thin film 40 increases in proportion to sizes of the nano-particles 30, other conditions being equal.

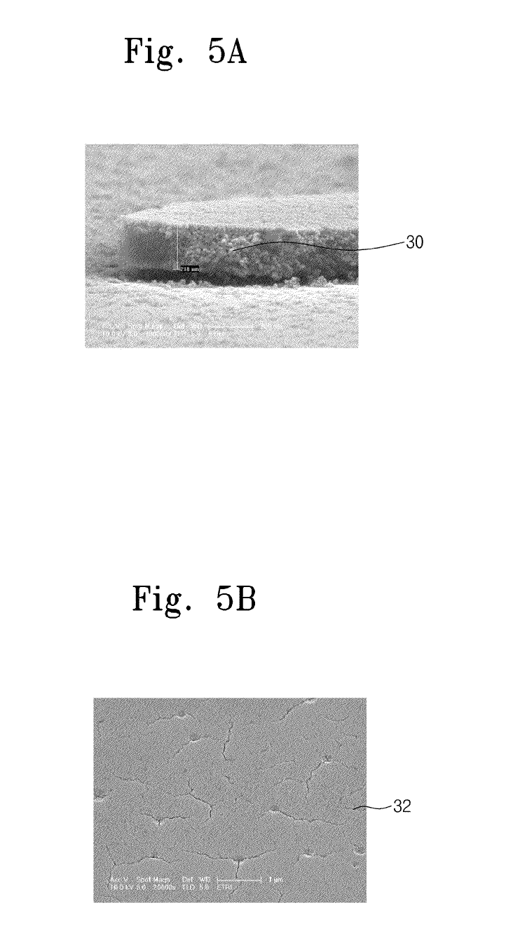

FIGS. 5A and 5B are images of thin films composed of the nano-particles 30.

Referring to FIGS. 5A and 5B, when the nano-particles 30 are formed as a single layer film without the support material 20 on a glass substrate by simply dispersing the nano-particles 30 in a dispersion solution which does not contain support material precursors and by using a sol-gel method, a plurality of cracks 32 may be generated. The nano-particles 30 may have diameters of about 10 nm and may include silicon oxide. The nano-particles 30 of silicon oxide may have a refractive index of about 1.34 less than a refractive index of about 1.5 of glass.

A small amount of the support material 20 may improve adhesive strength of the nano-particles 30. The thin film 40, in which a large amount of the silicon oxide nano-particles 30 is injected to the precursor solution 22 of aluminum oxide having a refractive index of about 1.7, may have a lower refractive index than that of glass. The thin film 40 may be an anti-reflective layer or high reflective layer having a refractive index of about 1.35 to about 1.37 on a glass substrate. The thin film 40 may have a refractive index higher than that of the nano-particles 30 and very lower than that of the support material 20. Therefore, by using the method for manufacturing the thin film 40 according to the embodiment of the inventive concept, a refractive index of the thin film 40 may be easily adjusted by adjusting amounts of the nano-particles 30 and the support material 20.

As described above, according to an exemplary structure of the inventive concept, a precursor solution of support material, in which nano-particles having a lower density than that of the support material are contained, is coated on a substrate, and the nano-particles are concentrated on an upper part due to a density difference between the nano-particles and the support material while the precursor solution-coated substrate is heat-treated. Accordingly, the surface roughness of a thin film can be increased.

Otherwise, a precursor solution of support material, in which nano-particles having a higher density than that of the support material are contained, is coated on a substrate, and the nano-particles are concentrated on a lower part of the support material due to a density difference between the nano-particles and the support material while the precursor solution is heat-treated. Accordingly, a lower part of a thin film has a higher density than that of an upper part thereof.

The nano-particles may be biasedly distributed on an upper part or lower part of a thin film. Therefore, the thin film has the same effect as a multi-layered thin film of which layers have different refractive indices.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A thin film comprising:
a support material, and particles contained therein,
wherein a density of the particles is different from that of the support material, and the particles are intensively concentrated on an upper or lower part of the support material.

2. The thin film of claim 1, wherein the particles have a lower density than that of the support material, and increase surface roughness at the upper part of the support material.

3. The thin film of claim 2, wherein the surface roughness increases in proportion to the density difference between the particles and the support material.

4. The thin film of claim 3, wherein the particles have a lower refractive index than that of the support material.

5. The thin film of claim 4, wherein the particles have diameters of about 1 nm to about 500 nms.

6. The thin film of claim 5, wherein the surface roughness is proportion to the diameters of the particles.

7. The thin film of claim 6, wherein the surface roughness is larger than about 1 nm and smaller than about 500 nms.

8. The thin film of claim 1, wherein the support material comprises at least one of aluminum oxide, titanium oxide, tantalum oxide, and zinc oxide.

9. The thin film of claim 1, wherein the particles comprise at least one of silicon oxide and silicon nitride.

10. The thin film of claim 1, wherein the particles have a higher density than that of the support material and are distributed on the lower part of the support material, and thus a lower part of the thin film has a higher refractive index than that of an upper part of the thin film.

11. The thin film of claim 1, wherein the particles have a density lower than 3.44 g/cm³ and a refractive index lower than 1.5.

12. The thin film of claim 1, wherein the support material has a density higher than 3.5 g/cm³ and a refractive index higher than 1.65.
